(19) United States
(12) Patent Application Publication
(10) Pub. No.: US 2026/0179671 A1
(43) Pub. Date: Jun. 25, 2026

(54) INVERTING MEMORY DEVICE, RELATED ELECTRONIC CIRCUIT, PROGRAMMING METHOD AND READING METHOD

(71) Applicant: Commissariat à l’Energie Atomique et aux Energies Alternatives, Paris (FR)

(72) Inventors: Julien BORREL, Grenoble Cedex 9 (FR); Mathieu FAYE, Grenoble Cedex 9 (FR); Sebastien RICAVY, Grenoble Cedex 9 (FR)

(73) Assignee: Commissariat à l’Energie Atomique et aux Energies Alternatives, Paris (FR)

(21) Appl. No.: 19/428,716

(22) Filed: Dec. 22, 2025

(30) Foreign Application Priority Data
Dec. 24, 2024 (FR) FR2415248

(51) Int. Cl. G11C 11/22

(52) U.S. Cl. CPC G11C 11/2275; G11C 11/223; G11C 11/2273

(57) ABSTRACT

A memory device includes a primary transistor including a primary gate electrode and first and second primary conduction electrodes; a secondary transistor including a secondary gate electrode and first and second secondary conduction electrodes; the secondary gate electrode being connected to the second primary conduction electrode of the primary transistor; and an impedance connected to the second primary conduction electrode and to the secondary gate electrode; the primary transistor being a ferroelectric field-effect transistor and the secondary transistor being a field-effect transistor.

### CROSS-REFERENCE TO RELATED APPLICATIONS

This application is a U.S. non-provisional application claiming the benefit of French Application No. 24 15248, filed on Dec. 24, 2024, which is incorporated herein by reference in its entirety.

### FIELD

The present invention relates to a memory device.

The invention also relates to an electronic circuit comprising a plurality of such memory devices; as well as a programming method for such a memory device and a reading method for such a memory device.

### BACKGROUND

The invention relates to the field of electronics, and in particular microelectronics.

Conventionally, a computing unit, such as a processor, for example a CPU (Central Processing Unit), and a storage unit, such as a memory, are physically separate and connected via a data bus, which implies a significant data transfer via this bus between the computing unit responsible for calculation operations and the storage unit responsible for storing operands, then the result of the calculation operations. The bandwidth of the data bus then often becomes a limiting factor, also known as the von Neumann bottleneck.

To mitigate this limiting factor, it is known to perform logic operations directly in the memory, this technological field also being called PIM (Processing In Memory).

A sub-domain of the PIM field is stateful logic, consisting of performing logic operations directly on memory points without needing to read and process the information stored there. The logic operation is done naturally and automatically as a function of how the memory points of which are connected to each other.

However, this technological sub-domain uses resistive components and therefore involves significant current consumption.

### SUMMARY

The aim of the invention is then to propose a memory device allowing a logic operation to be performed, while having a more limited current consumption.

To this end, the invention has as its object a memory device comprising:
a primary transistor including a primary gate electrode and first and second primary conduction electrodes;
a secondary transistor including a secondary gate electrode and first and second secondary conduction electrodes; the secondary gate electrode being connected to the second primary conduction electrode of the primary transistor; and
an impedance connected to the second primary conduction electrode and to the secondary gate electrode;
the primary transistor being a ferroelectric field-effect transistor and the secondary transistor being a field-effect transistor.

The memory device according to the invention, then allows a logic inversion operation to be performed directly in memory, the primary transistor serving to store the value to be inverted, and the secondary transistor then performing the conversion to achieve the inversion; all while having low current consumption, the primary transistor being a ferroelectric field-effect transistor and the secondary transistor being a field-effect transistor.

The skilled person will also observe that the impedance does not cause significant current consumption, as it is only traversed by a current during the reading phase.

According to other advantageous aspects of the invention, the memory device comprises one or more of the following characteristics, taken in isolation or according to all technically possible combinations:
the impedance presents a value equal to a resistance of the primary transistor when the primary transistor is in a non-conductive state;
the primary transistor is chosen from among the group consisting of: a ferroelectric gate oxide field-effect transistor, and a field-effect transistor with ferroelectric capacitance connected to the gate electrode; and
the secondary transistor is chosen from among the group consisting of: a ferroelectric gate oxide field-effect transistor, a field-effect transistor with ferroelectric capacitance connected to the gate electrode, and a field-effect transistor.

The invention also relates to an electronic circuit comprising a plurality of memory devices, a programming device for the memory devices, a reading device for the memory devices, each memory device being such as defined above.

According to other advantageous aspects of the invention, the electronic circuit comprises one or more of the following characteristics, taken in isolation or according to all technically possible combinations:
the circuit comprises word lines, pairs of source lines, and pairs of bit lines, and each memory device is connected to a respective word line, a respective pair of source lines, and a respective pair of bit lines;
the circuit comprises word lines, source lines, and bit lines; the primary transistor of each memory device is connected to a respective word line, a respective source line, and a respective bit line; and the secondary transistor and the impedance are integrated into the reading device; and
the electronic circuit comprises a substrate, a set of levels close to the substrate, called front end, for the connection of electronic component(s), and a set of levels distant from the substrate, called back end;
the primary transistor and the secondary transistor of each memory device being preferably included in the front end, the impedance of each memory device being then comprised in the back end; or
the primary transistor and the impedance of each memory device being preferably included in the back end, the secondary transistor of each memory device being then included in the front end.

The invention also relates to a programming method for a memory device such as defined above, comprising a programming phase during which an input potential is applied to the primary gate electrode.

According to other advantageous aspects of the invention, the programming method comprises one or more of the following characteristics, taken in isolation or according to all technically possible combinations:
during the programming phase, the first primary conduction electrode and the secondary conduction electrodes are connected to an electrical ground, and the second primary conduction electrode and the secondary gate electrode are connected to the electrical ground via the impedance;
during the programming phase, the primary transistor is biased at a low level if the input potential is greater than a programming potential, and at a high level if the input potential is less than the opposite of the programming potential.

The invention also relates a reading method for a memory device such as defined above, the memory device being configured to perform an inversion of a value previously written in the primary transistor via a programming method such as defined above, the reading method comprising a reading phase during which the primary transistor is in a non-biased state and the secondary transistor is in a polarized state, a result of the inversion corresponding to a value of the current passing through the secondary transistor.

According to other advantageous aspects of the invention, the reading method comprises one or more of the following characteristics, taken in isolation or according to all technically possible combinations:
for the non-biased state of the primary transistor, the primary gate electrode and the first primary conduction electrode are connected to an electrical ground, and for the biased state of the secondary transistor, a zero potential is applied to the first secondary conduction electrode, a reading potential of the secondary transistor is applied to the second secondary conduction electrode, and during the reading phase, the end of the impedance connected to the second primary conduction electrode receives a potential resulting from the prior programming of the primary transistor, and a potential equal to twice the threshold potential is applied to the other end of the impedance;
the result of the inversion is a binary value determined via the comparison of the value of the current passing through the secondary transistor with a predefined current threshold;
the result of the inversion being preferably equal to 1 if said value of the current is greater than the predefined current threshold, and 0 otherwise;
the value to be inverted, written in the primary transistor during the programming phase, corresponds to a level of biasing of the primary transistor resulting from the application of the input potential to the primary gate electrode;
the value to be inverted being preferably equal to 1 if the biasing of the primary transistor is at a low level, and at 0 if said biasing is at a high level;
if the primary transistor has been biased at a low level during its prior programming, then the secondary transistor is not conductive during the reading phase, and the result of the inversion is equal to 0; and if the primary transistor has been biased at a high level during its prior programming, then the secondary transistor is conductive during the reading phase, and the result of the inversion is equal to 1.

### BRIEF DESCRIPTION OF THE DRAWINGS

These characteristics and advantages of the invention will become clearer upon reading the following description, given solely by way of non-limiting example, and made with reference to the appended drawings, in which:

FIG. 1 is a schematic representation of an electronic circuit according to the invention, including blocks of memory devices, as well as a programming device and a reading device, connected to each of the blocks for programming, and respectively reading, said memory devices;

FIG. 2 is a schematic representation of a respective memory device, according to a first embodiment; and

FIG. 3 is a view similar to that of FIG. 2, according to a second embodiment.

### DETAILED DESCRIPTION

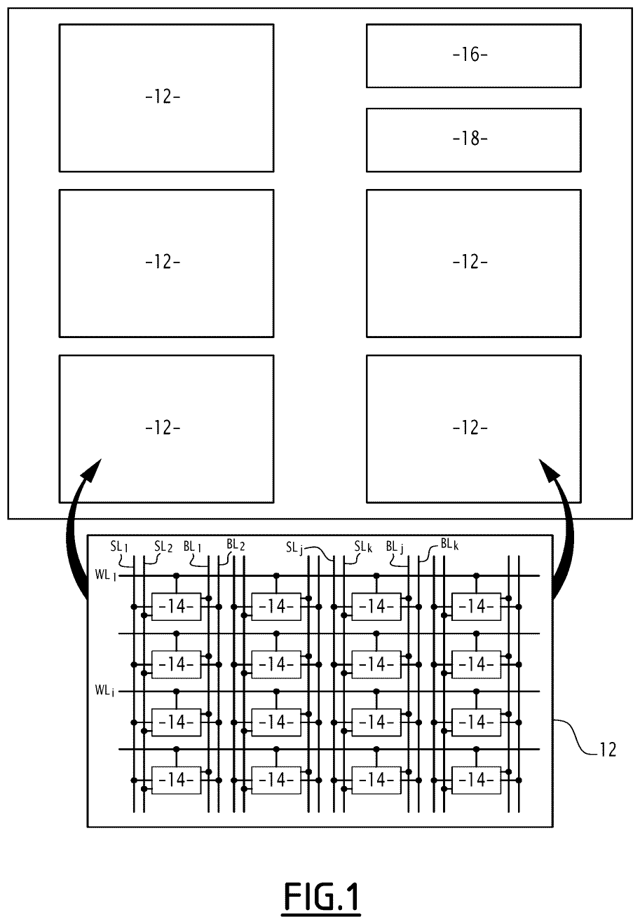

In FIG. 1, an electronic circuit 10 comprises one or more blocks 12 each including several memory devices 14, a programming device 16, and a reading device 18, the programming device 16 and respectively the reading device 18 being connected to each of the blocks 12 of the memory device 14.

The skilled person will observe that the number of blocks 12 included in the electronic circuit 10 is variable and typically depends on the amount of calculation operations to be performed per unit of time.

Each block 12 includes a plurality of memory devices 14, preferably arranged in the form of a two-dimensional matrix, with the memory devices 14 then distributed according to rows and columns.

Each block 12 also includes word lines WL, bit lines BL, and source lines SL. The source lines SL and the bit lines BL are advantageously parallel to each other; and the word lines WL are parallel to each other and perpendicular to the source lines SL and bit lines BL.

In the previous notations, a word line is referenced WL (Word Line); the bit lines are referenced with the acronym BL (Bit Line), and the source lines are referenced with the acronym SL (Source Line).

The number of memory devices 14 within each respective block 12 is variable, and also typically depends on the amount of calculation operations to be performed per unit of time, as well as the architecture chosen for the electronic circuit 10, notably the number of blocks 12 included in the electronic circuit 10.

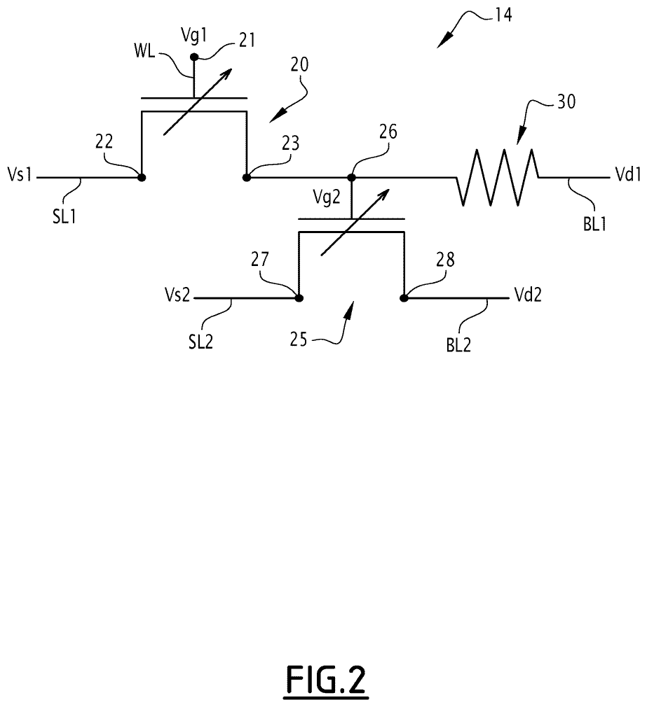

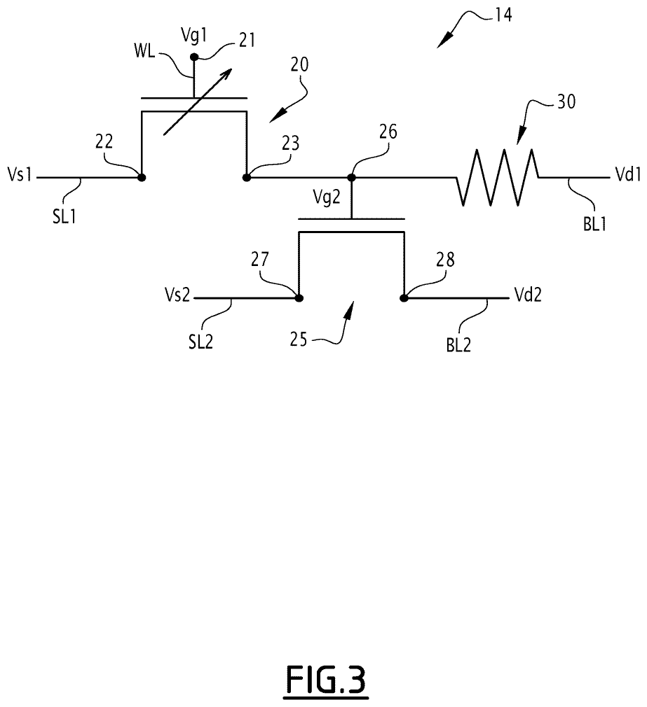

In the examples of FIGS. 2 and 3, the memory device 14 is connected to a respective word line WL; to a respective pair of source lines SL1, SL2, namely a first source line SL1 and a second source line SL2; and to a respective pair of bit lines BL1, BL2, namely a first bit line BL1 and a second bit line BL2.

In general, each memory device 14 is connected to a respective word line WLi, to a respective pair of source lines SLj, SLk, and to a respective pair of bit lines BLj, BLk; where i, j, and k are integer indices, the indices j being for example even and the indices k odd.

Each memory device 14 of the same row of the matrix shares the same word line WL, so that the word lines WL can also be indexed with the index i. Thus, the first word line, in other words the one that connects the memory devices 14 of the first row, can be referenced WL1.

The memory devices 14 of the same column share the same pair of bit lines BLj, BLk, and the same pair of source lines SLj, SLk. This pair of lines can therefore also be indexed with the indices j and k.

The memory devices 14 of the same row are then selectable by a word line WL, and the memory devices 14 of the same column are connected to a pair of bit lines BLj, BLk, and to a pair of source lines SLj, SLk.

Alternatively, the primary transistor 20 of each memory device 14 is connected to a respective word line WL, to a respective source line SL1, and to a respective bit line BL1, while the secondary transistor 25, the impedance 30, and the associated bit lines BL2 and source lines SL2 are integrated into the reading device 18. According to this alternative, the primary transistor 20 and the corresponding secondary transistor 25 are connected to each other by a bit line.

According to this alternative, only the primary transistors 20 of the memory devices 14 are then integrated within each respective block 12.

In addition, the electronic circuit 10 comprises a substrate, a set of levels close to the substrate, called front end, for the connection of electronic components, and a set of levels distant from the substrate, called back end, not represented. The front end is also noted FEOL (Front End Of Line), and the back end is also noted BEOL (Back End Of Line).

According to a first arrangement example, the primary transistor 20 and the secondary transistor 25 of each memory device 14 are included in the front end, and the impedance 30 of each memory device 14 is then included in the back end.

According to a second arrangement example, the primary transistor 20 and the impedance 30 of each memory device 14 are included in the back end, and the secondary transistor 25 of each memory device 14 is then included in the front end.

According to a third arrangement example, the primary transistor 20 and the impedance 30 of each memory device 14 are included in the front end, and the secondary transistor 25 of each memory device 14 is then included in the back end. According to this arrangement example, the secondary transistor 25 is advantageously arranged with its gate electrode, hereinafter secondary gate electrode 26, in a BackGated positioning.

The skilled person will observe that the primary transistor 20 and the secondary transistor 25 of each memory device 14 are preferably arranged on two different levels, namely one in the front end and the other in the back end, which then allows a gain in memory device 14 density per surface area.

Each memory device 14 comprises a primary transistor 20 including a primary gate electrode 21 and first 22 and second 23 primary conduction electrodes. The first 22 and the second 23 primary conduction electrodes are typically source and drain electrodes. In the examples of FIGS. 2 and 3, the first primary conduction electrode 22 is a source electrode, with an associated voltage Vs1, applied via the first source line SL1; and the second primary conduction electrode 23 is a drain electrode, with an associated voltage Vd1, applied via the first bit line BL1.

Each memory device 14 comprises a secondary transistor 25 including a secondary gate electrode 26 and first 27 and second 28 secondary conduction electrodes. The secondary gate electrode 26 is connected to the second primary conduction electrode 23 of the primary transistor 20. The first 27 and the second 28 secondary conduction electrodes are typically source and drain electrodes. In the examples of FIGS. 2 and 3, the first secondary conduction electrode 27 is a source electrode, with an associated voltage Vs2, applied via the second source line SL2; and the second secondary conduction electrode 28 is a drain electrode, with an associated voltage Vd2, applied via the second bit line BL2.

Each memory device 14 comprises an impedance 30 connected to the second primary conduction electrode 23 and to the secondary gate electrode 26.

The programming device 16 is configured to program each memory device 14, by implementing the programming method according to the invention for each memory device 14 to be programmed, the programming method being described in more detail below.

The programming device 16 is advantageously configured to program several memory devices 14 at once, and preferably simultaneously, as long as it does not require two distinct voltage values to be applied at the same time on the same word line WL, or on the same bit line BL, or on the same source line SL.

The reading device 18 is configured to read each memory device 14, by implementing the reading method according to the invention for each memory device 14 to be read, the reading method being described in more detail below.

The reading device 18 is advantageously configured to read several memory devices 14 at once, and preferably simultaneously, as long as it does not require two distinct voltage values to be applied or read at the same time on the same word line WL, or on the same bit line BL, or on the same source line SL.

The primary transistor 20 is a ferroelectric field-effect transistor. In the examples of FIGS. 2 and 3, the primary transistor 20 is a ferroelectric gate oxide field-effect transistor or FeFET (Ferroelectric Field-Effect Transistor). Alternatively, the primary transistor 20 is a field-effect transistor with ferroelectric capacitance connected to the gate electrode or FeMFET (Ferroelectric Metal Field-Effect Transistor).

The primary transistor 20 presents a primary threshold potential, noted Vth1, corresponding to the potential difference Vgs1 between its gate electrode and its source electrode, from which the primary transistor 20 is conductive.

The secondary transistor 25 is a field-effect transistor. In the example of FIG. 2, the secondary transistor 25 is a ferroelectric gate oxide field-effect transistor or FeFET, or a field-effect transistor with ferroelectric capacitance connected to the gate electrode or FeMFET. In the example of FIG. 3, the secondary transistor 25 is a field-effect transistor or FET (Field-Effect Transistor).

The secondary transistor 25 presents a secondary threshold potential, noted Vth2, corresponding to the potential difference Vgs2 between its gate electrode and its source electrode, from which the secondary transistor 25 is conductive.

The impedance 30 is a resistance in the examples of FIGS. 2 and 3. The impedance 30 advantageously presents a value equal to a resistance of the primary transistor 20 when the primary transistor 20 is in a non-conductive state.

The operation of the memory device 14 according to the invention will now be described, starting with the programming method implemented by the programming device 16, then continuing with the reading method implemented by the reading device 18.

The programming method comprises a programming phase during which an input potential Vg1 is applied to the primary gate electrode 21, in order to bias the primary transistor 20.

During the programming phase, the first primary conduction electrode 22 and the secondary conduction electrodes 27, 28 are connected to an electrical ground, not represented. The second primary conduction electrode 23 and the secondary gate electrode 26 are connected to the electrical ground via the impedance 30. In other words, the voltages Vs1, Vs2, Vd2 applied respectively to the first primary conduction electrode 22 and to the secondary conduction electrodes 27, 28 are each substantially zero. Similarly, the voltages Vd1, Vg2 applied respectively to the second primary conduction electrode 23 and to the secondary gate electrode 26 are each substantially zero. In other words, Vs1≈Vs2≈Vd2≈0 and Vd1≈Vg2≈0.

During the programming phase, the primary transistor 20 is biased at a low level if the input potential Vg1 is greater than a programming potential Vprog of the primary transistor 20. Conversely, the primary transistor 20 is biased at a high level if the input potential Vg1 is less than the opposite −Vprog of said programming potential Vprog.

Thus, to store information in the memory device 14, the programming device 16 is configured to apply the input potential Vg1 to the primary gate electrode 21 and to connect to the electrical ground the other electrodes, namely the primary conduction electrodes 22, 23, the secondary conduction electrodes 27, 28, and the secondary gate electrode 26, in order to bias the primary transistor 20. The input potential Vg1 applied is a strong positive voltage, in other words greater than the programming potential Vprog; or a strong negative voltage, in other words less than the opposite −Vprog of the programming potential.

The information stored in the primary transistor 20 then results in a high primary threshold potential Vth1 when the primary transistor 20 is biased at the high level with Vg1<−Vprog; and conversely by a low primary threshold potential Vth1 when the primary transistor 20 is biased at the low level with Vg1>Vprog.

The reading method of the memory device 14 according to the invention, aimed at performing a logic inversion of a value previously written in the primary transistor 20 via the programming method according to the invention described above, will now be described.

The reading method comprises a reading phase during which the primary gate electrode 21 of the primary transistor 20 is in a non-biased state and the effective biasing of the secondary gate electrode 26 of the secondary transistor 25 depends on the state stored in the primary transistor 20, the result of the inversion corresponding to a current value through the secondary transistor 25.

Thus, to read the memory device 14, and in particular to perform the logic inversion of the value, or information, previously stored in the primary transistor 20 by the programming device 16 during the programming phase, the reading device 18 is configured to put the primary gate electrode 21 of the primary transistor 20 in the non-biased state and to simultaneously bias the voltages Vd1 and Vd2, in order to read the current value passing through the secondary transistor 25 and representing the result of the inversion.

For the non-biased state of the primary transistor 20, the primary gate electrode 21 and the first primary conduction electrode 22 are connected to the electrical ground. In other words, to put the primary transistor 20 in the non-biased state, the reading device 18 is configured to connect the primary gate electrode 21 and the first primary conduction electrode 22 to the electrical ground. Thus, the voltages Vg1, Vs1 applied respectively to the primary gate electrode 21 and to the first primary conduction electrode 22 are each substantially zero, that is, Vg1≈Vs1≈0.

For the biased state of the secondary transistor 25, a zero potential is applied to the first secondary conduction electrode 27, this being connected to the ground, a reading potential Vread of the secondary transistor 25 is applied to the second secondary conduction electrode 28, and during the reading phase, the end of the impedance 30 connected to the second primary conduction electrode 23 receives a potential resulting from the prior programming of the primary transistor 20, and a potential equal to twice the secondary threshold potential Vth2 being applied to the other end of the impedance 30. The reading potential Vread of the secondary transistor 25 is for example of the order of 100 mV.

In other words, to bias the secondary transistor 25 and read the value of the current passing through the secondary transistor 25 and representing the result of the inversion, the reading device 18 is configured to apply twice the secondary threshold potential Vth2 to the end of the impedance 30 that is connected to the first bit line BL1, that is, Vd1≈2*Vth2; to apply the zero potential to the first secondary conduction electrode 27, that is, Vs2≈0; and to apply the reading potential Vread to the second secondary conduction electrode 28, that is, Vd2≈Vread.

During this reading phase, the secondary gate electrode 26 receives the potential resulting from the prior programming of the primary transistor 20, via the second primary conduction electrode 23.

Thus, depending on the information previously stored in the primary transistor 20, the secondary transistor 25 will be conductive or not. The result of the inversion is then a binary value determined via the comparison of the value of the current through the secondary transistor 25 with a predefined current threshold. The result of the inversion is, for example, equal to 1 if said value of the current is greater than the predefined current threshold, and 0 otherwise.

The skilled person will understand that the value to be inverted, written in the primary transistor 20 during the programming phase, corresponds to the level of biasing of the primary transistor 20 resulting from the programming phase. The value to be inverted is for example defined equal to 1 if the biasing of the primary transistor 20 is at a low level, and correspondingly to 0 if said biasing is at a high level.

Also, if the primary transistor 20 has been biased at the low level during its prior programming, corresponding to the stored value equal to 1, then the primary transistor 20 is conductive for a substantially zero voltage applied to its primary gate electrode 21, and the secondary transistor 25 is therefore not conductive, that is, blocked, during this reading phase. Indeed, the voltage Vg2 is then equal to the voltage Vs1, itself substantially zero, that is, Vs1≈Vg2≈0. The reading device 18 then does not measure any current passing through the secondary transistor 25, and the result of the inversion is equal to 0. The stored value equal to 1 has therefore been correctly inverted to the value 0.

Conversely, if the primary transistor 20 has been biased at the high level during its prior programming, corresponding to the stored value equal to 0, then the primary transistor 20 is not conductive, that is, blocked, for a substantially zero voltage applied to its primary gate electrode 21, and the secondary transistor 25 is in this case conductive during this reading phase. Indeed, the voltage Vg2 is then equal to the voltage Vd1/2 if the value of the impedance 30 is equal to the resistance of the primary transistor 20 in its non-conductive state, that is, Vg2≈Vd1/2≈Vth2, and as Vs1≈Vg1≈0 and Vs2≈0, Vd2≈Vread, then the potential difference between the secondary gate electrode 26 and the first secondary conduction electrode 27 forming the source electrode, that is, Vgs2, is equal to the secondary threshold potential Vth2 of the secondary transistor 25, that is, Vgs2=Vg2−Vs2≈Vth2≈Vd1/2, and it is therefore conductive. The reading device 18 then measures a current value greater than the predefined current threshold through the secondary transistor 25, and the result of the inversion is equal to 1. The stored value equal to 0 has therefore been correctly inverted to the value 1.

The skilled person will observe that the operation of the memory device 14 according to the invention is the same whether the secondary transistor 25 is a ferroelectric field-effect transistor, that is, FeFET, according to the first embodiment of FIG. 2, or whether the secondary transistor 25 is a field-effect transistor, that is, FET, according to the second embodiment of FIG. 3.

Thus, the memory device 14, according to the invention, allows a logic operation, namely logic inversion, to be performed directly in memory, that is, an inversion in PIM, while having limited current consumption.

1. A memory device comprising:
a primary transistor including a primary gate electrode and first and second primary conduction electrodes;
a secondary transistor including a secondary gate electrode and first and second secondary conduction electrodes; the secondary gate electrode being connected to the second primary conduction electrode of the primary transistor; and
an impedance connected to the second primary conduction electrode and to the secondary gate electrode;
the primary transistor being a ferroelectric field-effect transistor and the secondary transistor being a field-effect transistor.

2. The memory device according to claim 1, wherein the impedance presents a value equal to a resistance of the primary transistor when the primary transistor is in a non-conductive state.

3. The memory device according to claim 1, wherein the primary transistor is chosen from among the group consisting of: a ferroelectric gate oxide field-effect transistor, and a field-effect transistor with ferroelectric capacitance connected to the gate electrode.

4. The memory device according to claim 1, wherein the secondary transistor is chosen from among the group consisting of: a ferroelectric gate oxide field-effect transistor, a field-effect transistor with ferroelectric capacitance connected to the gate electrode, and a field-effect transistor.

5. An electronic circuit comprising a plurality of memory devices, a programming device for the memory devices, a reading device for the memory devices, each memory device being according to claim 1.

6. The electronic circuit according to claim 5, wherein the circuit comprises word lines, pairs of source lines, and pairs of bit lines, and each memory device is connected to a respective word line, a respective pair of source lines, and a respective pair of bit lines.

7. The electronic circuit according to claim 5, wherein the circuit comprises word lines, source lines, and bit lines; the primary transistor of each memory device is connected to a respective word line, a respective source line, and a respective bit line; and the secondary transistor and the impedance are integrated into the reading device.

8. The electronic circuit according to claim 5, wherein the electronic circuit comprises a substrate, a set of level(s) close to the substrate, called front end, for the connection of electronic components, and a set of level(s) distant from the substrate, called back end.

9. The electronic circuit according to claim 8, wherein the primary transistor and the secondary transistor of each memory device are included in the front end, the impedance of each memory device being then included in the back end.

10. The electronic circuit according to claim 8, wherein the primary transistor and the impedance of each memory device are included in the back end, the secondary transistor of each memory device being then included in the front end.

11. A programming method for a memory device according to claim 1, comprising a programming phase during which an input potential is applied to the primary gate electrode.

12. The programming method according to claim 11, wherein, during the programming phase, the first primary conduction electrode and the secondary conduction electrodes are connected to an electrical ground, and the second primary conduction electrode and the secondary gate electrode are connected to the electrical ground via the impedance.

13. The programming method according to claim 12, wherein, during the programming phase, the primary transistor is biased at a low level if the input potential is greater than a programming potential, and at a high level if the input potential is less than the opposite of the programming potential.

14. A reading method for a memory device according to claim 1, the memory device being configured to perform an inversion of a value previously written in the primary transistor via a programming method according to claim 11, the reading method comprising a reading phase during which the primary transistor is in a non-biased state and the secondary transistor is in a biased state, a result of the inversion corresponding to a value of the current through the secondary transistor.

15. The reading method according to claim 14, wherein, for the non-biased state of the primary transistor, the primary gate electrode and the first primary conduction electrode are connected to an electrical ground, and for the biased state of the secondary transistor, a zero potential is applied to the first secondary conduction electrode, a reading potential of the secondary transistor is applied to the second secondary conduction electrode, and during the reading phase, the end of the impedance connected to the second primary conduction electrode receives a potential resulting from the prior programming of the primary transistor, and a potential equal to twice the threshold potential is applied to the other end of the impedance.

16. The reading method according to claim 14, wherein the result of the inversion is a binary value determined via the comparison of the value of the current through the secondary transistor with a predefined current threshold.

17. The reading method according to claim 16, wherein the result of the inversion is equal to 1 if said value of the current is greater than the predefined current threshold, and 0 otherwise.

18. The reading method according to claim 14, wherein the value to be inverted, written in the primary transistor during the programming phase, corresponds to a level of biasing of the primary transistor resulting from the application of the input potential to the primary gate electrode.

19. The reading method according to claim 18, wherein the value to be inverted is equal to 1 if the biasing of the primary transistor is at a low level, and 0 if said biasing is at a high level.

20. The reading method according to claim 18, wherein, if the primary transistor has been biased at a low level during its prior programming, then the secondary transistor is not conductive during the reading phase, and the result of the inversion is equal to 0; and if the primary transistor has been biased at a high level during its prior programming, then the secondary transistor is conductive during the reading phase, and the result of the inversion is equal to 1.
